(19) United States
(12) Patent Application Publication
(10) Pub. No.: US 2023/0012890 A1
(43) Pub. Date: Jan. 19, 2023

(54) METHOD FOR NANOSTRUCTURING A SUBSTRATE

(71) Applicants: ARKEMA FRANCE, COLOMBES (FR); CENTRE NATIONAL DE LA RECHERCHE SCIENTIFIQUE, PARIS (FR); UNIVERSITE GRENOBLE ALPES, SAINT MARTIN D'HERES (FR)

(72) Inventors: Xavier Chevalier, Grenoble (FR); Marc Zelsmann, Biviers (FR); Christophe Navarro, Bayonne (FR); Gwenaëlle Pound-Lana, Grenoble (FR)

(21) Appl. No.: 17/787,406

(22) PCT Filed: Dec. 29, 2020
(86) PCT No.: PCT/EP2020/088007

§ 371 Date: Jun. 20, 2022

(30) Foreign Application Priority Data
Dec. 31, 2019 (FR) FR1915802

(51) Int. Cl. G03F 7/00; B82Y 40/00

(52) U.S. Cl. CPC G03F 7/0002; B82Y 40/00

(57) ABSTRACT

The invention relates to a method for nanostructuring a substrate (10) for the preparation of a nanostructured substrate having nanostructures of different dimensions, the method including removing the crosslinked polymer layer (TC) and one of the blocks of the nanostructured block copolymer so as to form patterns of a nanolithography mask; said method being characterized in that the removal of one of the blocks is a removal of only a portion of the nanodomains (21, 22) of one of the blocks of the nanostructured block copolymer, in particular of only the perpendicular nanodomains (Z1) of said block, such that the parallel nanodomains (21, 22) of at least two blocks of the nanostructured block copolymer form patterns of the nanolithography mask; and so as to generate in the nanolithography mask patterns (M1, M2, M3) of different dimensions and nanostructures in the nanostructured substrate of different dimensions after etching.

### FIELD OF THE INVENTION

The present invention relates to the field of directed self-assembly, also called DSA (from the English acronym “Directed Self-Assembly”) nanolithography.

More particularly, the invention relates to a method for manufacturing a block copolymer film for use as a nanolithography mask comprising patterns of different periods for the nanostructuring of a substrate having nanostructures of different dimensions.

### PRIOR ART

Since the 1960s, block copolymers (BCPs) have been a very broad field of research for the development of new materials. It is possible to modulate and control their properties by the chemical nature of the blocks and their architecture for the intended application. For specific macromolecular parameters (Me, Iₚ, f, χ, N), block copolymers are capable of self-assembling and forming structures, the characteristic dimensions (10-100 nm) of which constitute today a major challenge in the field of microelectronics and microelectromechanical systems (MEMS). In the particular context of applications in the field of directed self-assembly, or DSA (English acronym for “Directed Self-Assembly”), nanolithography, block copolymers, which are capable of nanostructuring at an assembly temperature, are used as nanolithography masks. Block copolymers, once nanostructured, allow cylinders, lamellae, spheres, or even gyroids to be obtained which respectively form patterns, for creating nanolithography masks, with a periodicity that can be less than 20 nm, which is difficult to achieve with conventional lithography techniques. This periodicity is very appreciable when one wishes to create nanostructures all having the same dimension, in order to obtain identical properties (electrical conductivity, heat dissipation, etc.) for different spatially isolated structures on a substrate.

However, existing nanolithography masks usually have a single repeating pattern over their entire surface. However, for particular applications, it can be interesting to produce a mask with patterns, the period of which varies, to transfer them into an underlying substrate. In particular, for some applications in microelectronics, the aim is to produce block copolymer films in which the patterns created have different periods, while exhibiting a minimum of defects, the dimensions of the patterns ranging from less than 10 nm to about 100 nm and being transferable into an underlying substrate by dry etching.

Thus, it has been proposed, when one wishes to produce structures of different periods, to have several block copolymers of different periods, to dispense them, to assemble each one separately, to etch them, etc., increasing considerably the cost, and thus decreasing enormously the global productivity of the method, and thus its attractiveness in terms of structuring technique.

It is therefore desirable to be able to produce patterns of different periods in a single block copolymer film, all without generating defects in the block copolymer assembly. This last point is particularly delicate to achieve. Indeed, the more the block copolymer is forced to deviate from its natural period of equilibrium, the more it will tend to generate defective structures, the stress being then equivalent to a compression or expansion of the naturally orienting domains. Different block copolymer systems existing in the literature could address this problem of multi-periodicity, such as for example:
Multiblock copolymers, as described in the example of Yutaka Nagata et al., Macromolecules, 2005, 38, 24, 10220-10225, can have varying periods due to the property of polymer chains to form loops within the domains of the final assembly. However, these are “discrete” periods, depending on the dimension of the individual blocks in question. It should also be noted that as the number of blocks increases in a block copolymer, self-organization kinetics are slowed down, thus limiting the possibility of a defect-free structure within a reasonable time.
Block copolymers with different structures, for example multiblock star-shaped copolymers. These block copolymers, however, have the same disadvantages as the multiblock copolymers described above and their synthesis is very delicate.
Mixtures of block copolymers with different additives (block copolymers, homopolymers, small molecules . . . ) seem to be an interesting approach, especially since the final dimensions will not necessarily be discrete.

In the context of directed self-assembly nanolithography of block copolymers BCPs, a flat, that is to say no dewet, block copolymer film is sought with perpendicular nanodomains in order to be able to transfer these nanodomains into the underlying substrate to create dimensionally controlled patterns useful for microelectronics applications. In order to address these issues, the applicant showed, in patent applications FR 3 074 180 and FR 3 074 179, that the crosslinking of “top-coat” TC films, with neutral affinity with respect to the blocks of the underlying block copolymer, allowed flat top-coat and block copolymer films to be obtained, thanks to the mechanical stress imposed by crosslinking the top-coat. To this end, a crosslinking activator, such as a photo-generated acid (PAG), a photo-generated base (PBG), or a radical generator for example, is incorporated into the top-coat material and an appropriate stimulation of the activator, for example by UV radiation or an electron beam or thermal treatment, allows the top-coat film to be crosslinked.

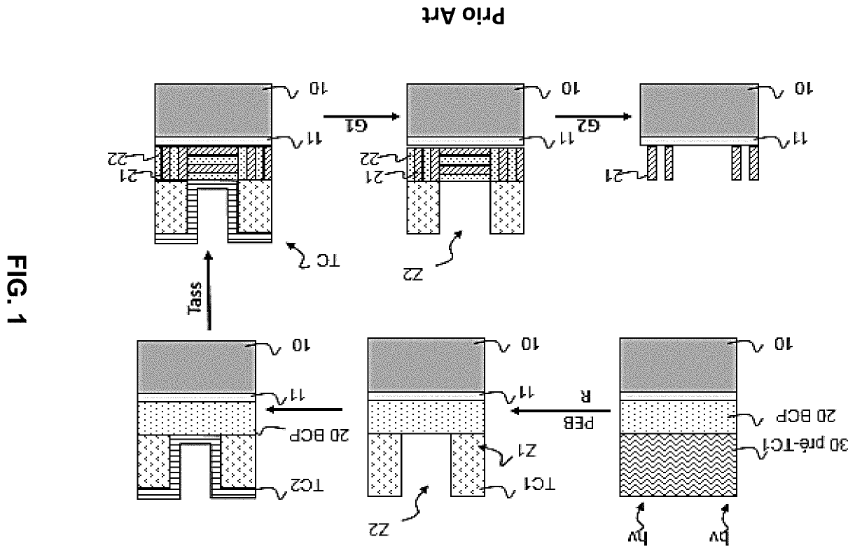

These documents further describe that such crosslinking of the top-coat film can furthermore be carried out in a localized manner, through a lithography mask, in order to obtain localized crosslinking of the top-coat with areas crosslinked and neutral with respect to the underlying block copolymer blocs, referenced Z1 in FIG. 1, and non-crosslinked areas Z2. Such localized crosslinking is intended to create specific areas in the underlying block copolymer 20, located under the crosslinked neutral areas Z1 of the top-coat TC1, where the nanodomains are oriented perpendicular to the substrate surface after annealing at the assembly temperature. However, in this case, the method followed to create specific areas of the BCP where the nanodomains are oriented perpendicular to the substrate surface is difficult to implement. Indeed, after the lithography step, allowing to locally crosslink some areas Z1 of the top coat TC1, it is necessary to remove the non-irradiated and thus non-crosslinked areas Z2 of top coat material TC1, and then replenish these with a second top coat TC2 of an affinity opposite to the first (that is to say if the first TC1 is neutral, then the second TC2 is non-neutral, and vice versa), and crosslink this second top coat TC2 in order to obtain the flatness of the underlying block copolymer film 20 in these same areas. Conversely, if a second top coat TC2 is not used and then crosslinked to ensure flatness of the underlying BCP film, the block copolymer may be free to dewet from these areas, which can be problematic when reduced thicknesses of the first top coat 1 TC1 are used, typically when the thickness of TC1 is less than twice that of the underlying BCP. In addition, a first etch G1 is required to remove the second crosslinked top coat layer, and then a second etch G2 is required to etch the residual top coat layer, and finally a third etch is required to transfer the resulting patterns into the underlying substrate.

The deposition and crosslinking of two top coats TC1 and TC2 of opposite affinity with respect to the blocks of the block copolymer allows areas with patterns oriented perpendicular to the interfaces and areas with patterns oriented parallel to the interfaces to be created in a same block copolymer film. By varying the dimension of the non-neutral and neutral crosslinked areas in the two top coat layers TC1 and TC2, it is possible to define parallel and perpendicular patterns, of varying dimensions, in the underlying block copolymer. However, such a method involves many steps, making it time-consuming and costly to implement.

The applicant has therefore sought a solution to simplify this method and allow the manufacture of a block copolymer film comprising patterns of different periods, in particular for applications in the field of microelectronics, offering a wider choice of masks for the production of semiconductors or integrated circuits.

### Technical Problem

The aim of the invention is thus to overcome at least one of the drawbacks of the prior art. The invention aims in particular to provide a simple and effective method for producing a block copolymer film for use as a nanolithography mask for the nanostructuring of a substrate, said block copolymer being capable of nanostructuring with a single period, said method allowing, in said block copolymer film, patterns of different periods to be produced, without generating defects.

### BRIEF DESCRIPTION OF THE INVENTION

To this end, the invention relates to a method for nanostructuring a substrate for the preparation of a nanostructured substrate having nanostructures of different dimensions, said method comprising the following steps:
Generating a guide surface over a substrate;
Depositing an unassembled block copolymer layer on the guide surface, said unassembled block copolymer layer being capable of forming, after assembly, a nanostructured block copolymer in the form of nanodomains;
Forming a crosslinked polymer layer over the unassembled block copolymer layer;
Annealing at a temperature corresponding to the assembly temperature of the unassembled block copolymer layer;
Removing the crosslinked polymer layer and one of the blocks of the nanostructured block copolymer so as to form patterns of a nanolithography mask;
Etching the substrate by means of said nanolithography mask;

said method being characterized in that:
said guide surface has areas neutral and non-neutral with respect to the unassembled block copolymer layer, at least one of said neutral or non-neutral areas of the guide surface having a first dimension;
said crosslinked polymer layer has areas neutral and non-neutral with respect to the unassembled block copolymer layer, at least one of said non-neutral areas of the crosslinked polymer layer having a second dimension;
said removal of one of the blocks being a removal of only part of the nanodomains of one of the blocks of the nanostructured block copolymer, in particular of only the perpendicular nanodomains of said block, so that the parallel nanodomains of at least two blocks of the nanostructured block copolymer form patterns of the nanolithography mask; and
said first and second dimensions are different so as to generate in the nanolithography mask patterns of different dimensions and nanostructures in the nanostructured substrate of different dimensions after etching.

The method according to the invention allows different dimensions to be created in the nanolithography mask independently of the natural period of the block copolymer. In addition, the process allows stacks of blocks parallel to the substrate, formed at the non-neutral areas to be used as a lithography resin, and then these patterns to be transferred into the substrate at the same time as those of the block copolymer.

Advantageously, the method also allows the shape and dimensions thus described in the nanolithography mask to be varied at will. Thus, it is possible to multiply the different dimensions for a same pattern addressed on the same area of the substrate.

In addition, the non-neutral areas of the guide surface and/or of the crosslinked polymer layer are therefore of particular interest in the context of the invention herein. These areas from non-neutral areas consist of the two blocks of the block copolymer.

According to Other Optional Features of the Method, the Latter May Optionally Include One or More of the Following Features, Alone or in Combination:
the non-crosslinked block copolymer layer has a thickness at least equal to 10 nm;
the crosslinked polymer layer has at least one non-neutral area of a dimension different from the neutral area;
the generation of a guide surface over a substrate involves implementing chemoepitaxy or graphoepitaxy;
the guide surface has guide resin increased thicknesses and the increased thicknesses have etching properties similar to one of the blocks of the block copolymer;
the guide resin forming the increased thicknesses is non-neutral with respect to the block copolymer;
the guide resin forming the increased thicknesses is neutral with respect to the block copolymer;
etching of the guide resin is carried out in a positive mode;
etching of the guide resin is carried out in a negative mode;
the areas of the block copolymer located under the neutral areas of the crosslinked polymer layer have nanodomains oriented perpendicular to the interfaces and the dimension of the nanodomains corresponds to the first dimension of the non-neutral areas;
the areas of the block copolymer located under the non-neutral areas of the crosslinked polymer layer have nanodomains oriented parallel to the interfaces and the dimension of the nanodomains corresponds to the first dimension of the non-neutral areas
the block copolymer comprises at least one block where a heteroatom such as silicon, germanium, titanium, hafnium, zirconium, or aluminum is present in all or part of the (co)monomers constituting said block.
the crosslinked polymer layer comprises at least two non-neutral reticulated areas which have mutually different dimensions.
the formation of a crosslinked polymer layer over the unassembled block copolymer layer includes the following sub-steps:
   Depositing a first layer of a prepolymer composition on the unassembled block copolymer layer;
   Reacting by locally crosslinking the molecular chains within said first prepolymer composition layer so as to generate a locally crosslinked polymer layer;
   Rinsing the locally crosslinked polymer layer in order to remove the non-crosslinked areas;
   Depositing a second prepolymer composition layer at least on the unassembled block copolymer layer;
   Reacting by locally crosslinking the molecular chains within said prepolymer composition second layer so as to generate a crosslinked polymer layer.
the formation of a crosslinked polymer layer over the unassembled block copolymer layer includes the following sub-steps:
   depositing a prepolymer composition layer comprising, on the one hand, a plurality of functional monomers and at least one crosslinkable functional group within its polymer chain and, on the other hand, two chemically different crosslinking agents, each agent being capable of initiating the crosslinking of said prepolymer in response to a stimulation specific thereto, and
   carrying out two successive crosslinking operations in primary and secondary areas of said layer, by successively stimulating the two crosslinking agents, in order to cause a crosslinking reaction of the molecular chains of said prepolymer by the successive action of the first crosslinking agent in said primary areas subjected to said first stimulation and then of the second crosslinking agent in said secondary areas subjected to said second stimulation in order to obtain a crosslinked polymer layer in which the different primary and secondary crosslinked areas have an opposite affinity with respect to the blocks of the underlying block copolymer.

Other advantages and features of the invention will appear upon reading the following description given by way of illustrative and non-limiting example, with reference to the appended figures:

FIG. 1 represents a diagram of a method for nanostructuring a substrate according to the prior art.

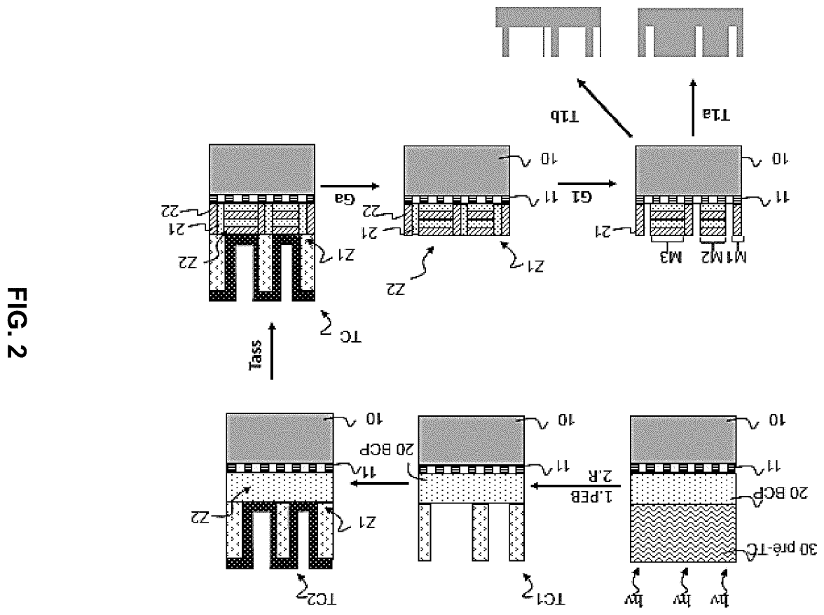

FIG. 2 represents a diagram of a method for nanostructuring a substrate according to one embodiment of the invention.

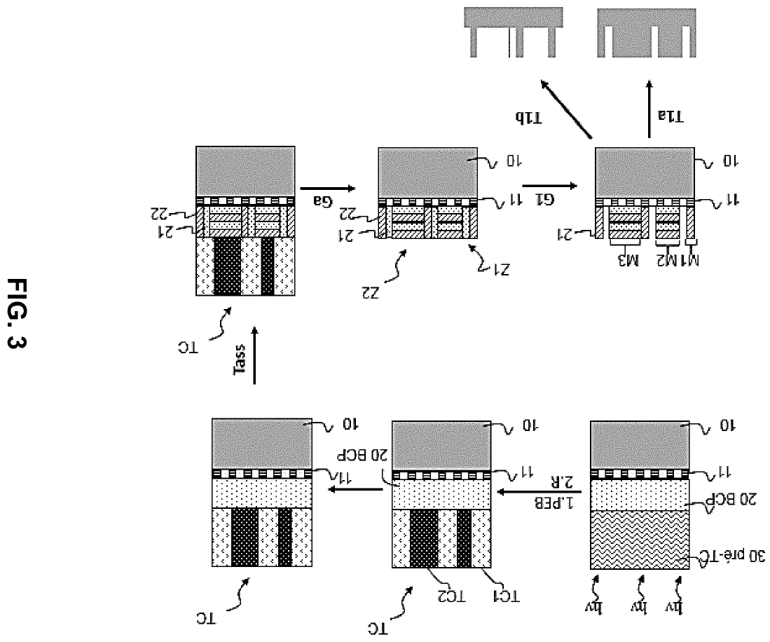

FIG. 3 represents a diagram of a method for nanostructuring a substrate according to one embodiment of the invention.

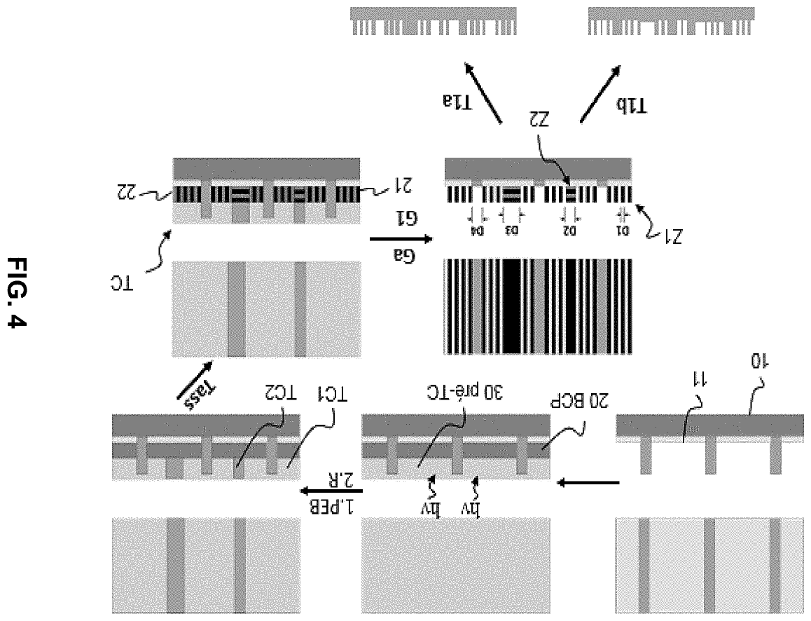

FIG. 4 represents a diagram of a method for nanostructuring a substrate according to one embodiment of the invention.

In the following description, by “polymer” is meant either a copolymer (of the statistical, gradient, block, alternating type), or a homopolymer.

The term “prepolymer” as used refers to at least one monomer and/or dimer and/or oligomer and/or polymer having reactive groups allowing it to participate in subsequent polymerization or crosslinking and thus to incorporate several monomer units into at least one chain of the final macromolecule.

By “polymer chain of a prepolymer” is meant the main chain of assembly of a plurality of monomer units, with other less important chains being considered as branches of the polymer main chain.

The term “monomer” as used refers to a molecule that can undergo polymerization.

The term “polymerization” as used refers to the method of transforming a monomer or mixture of monomers into a polymer of predefined architecture (block, gradient, statistical . . . ).

By “copolymer” is meant a polymer combining several different monomer units.

By “statistical copolymer” is meant a copolymer in which the distribution of the monomer units along the chain follows a statistical law, for example of the Bernoullian (zero-order Markov) or first- or second-order Markovian type. When the repeating units are randomly distributed along the chain, the polymers were formed by a Bernoulli method and are called random copolymers. The term random copolymer is often used, even when the statistical process that prevailed during the synthesis of the copolymer is not known.

By “gradient copolymer” is meant a copolymer in which the distribution of the monomer units varies gradually along the chains.

By “alternating copolymer” is meant a copolymer comprising at least two monomer entities which are distributed alternately along the chains.

By “block copolymer” is meant a polymer comprising one or more uninterrupted sequences of each of the separate polymer species, with the polymer sequences being chemically different from each other and being bonded together by a chemical (covalent, ionic, hydrogen, or coordination) bond. These polymer sequences are also referred to as polymer blocks. These blocks have a phase segregation parameter (Flory-Huggins interaction parameter) such that, if the degree of polymerization of each block is greater than a critical value, they are not miscible with each other and separate into nanodomains.

The above-mentioned term “miscibility” refers to the ability of two or more compounds to completely blend to form a homogeneous or “pseudo-homogeneous” phase, that is to say without apparent crystalline or near-crystalline symmetry over short or long distances. The miscibility of a mixture can be determined when the sum of the glass transition temperatures (Tg) of the mixture is strictly less than the sum of the Tgs of the individual compounds taken alone.

In the description, “self-assembly”, “self-organization” or “nanostructuring” are equally used to describe the well-known phenomenon of phase separation of block copolymers, at an assembly temperature also called the annealing temperature.

By “neutral” or “pseudo-neutral” surface is meant a surface which, as a whole, does not have a preferential affinity with any of the blocks of a block copolymer. It thus allows an equitable or “pseudo-equitable” distribution of the blocks of the block copolymer on the surface. Neutralization of the surface of a substrate allows such a “neutral” or “pseudo-neutral” surface to be obtained.

By “non-neutral” surface is meant a surface which, as a whole, has a preferential affinity with one of the blocks of a block copolymer. It allows the nanodomains of the block copolymer to be oriented in a parallel or non-perpendicular manner.

The surface energy (denoted γx) of a given material “x” is defined as the excess energy at the surface of the material compared to that of the material within its bulk. When the material is in liquid form, its surface energy is equivalent to its surface tension.

When talking about surface energies or more precisely interfacial tensions of a given material and a given block of a block copolymer, these are compared at a given temperature, and more precisely at a temperature allowing self-organization of the block copolymer.

By “lower interface” of a block copolymer is meant the interface in contact with an underlying layer or substrate on which said block copolymer is deposited. It should be noted that this lower interface is neutralized by a conventional technique, that is to say it does not, as a whole, have any preferential affinity with one of the blocks of the block copolymer.

By “upper interface” or “upper surface” of a block copolymer is meant the interface in contact with a top layer, called the top coat and denoted TC, applied to the surface of said block copolymer. It is noted that the top coat TC upper layer can preferably have both areas having a preferential affinity with one of the blocks of the block copolymer and areas having no preferential affinity with one of the blocks of the block copolymer so that the nanodomains of the block copolymer can be oriented parallel and perpendicular to the interfaces, respectively, at the time of the assembly annealing according to the areas facing the assembled block copolymer.

By “solvent orthogonal to a (co)polymer” is meant a solvent not capable of attacking or dissolving said (co)polymer.

By “liquid polymer” or “viscous polymer” is meant a polymer which, at a temperature greater than the glass transition temperature, has, due to its rubbery state, an increased capacity for deformation as a result of the possibility given to its molecular chains to move freely. The hydrodynamic phenomena at the origin of dewetting appear as long as the material is not in a solid state, that is to say non-deformable due to the negligible mobility of its molecular chains.

By “discontinuous film” is meant a film, the thickness of which is not constant due to the shrinkage of one or more areas, leaving holes.

By “pattern” in a nanolithography mask is meant an area of a film comprising a succession of alternating recessed and protruding shapes, wherein said area has a desired geometric shape, and the recessed and protruding shapes may be lamellae, cylinders, spheres, or gyroids.

By “dimension” or “D” is meant, within the meaning of the invention, a length, a width, a depth, a height, a thickness, a diameter.

By “equivalent” or “identical” or “of the same dimension” is meant, within the meaning of the invention, a variation between two measured values or between a measured value and a desired value of less than 20%, preferably less than 10%. By “non-equivalent” or “different” is meant a difference between a measured value and a desired or predetermined value or between two measured values of more than 10%, preferably more than 20%.

In the remainder of the invention, by “crosslinked polymer layer” is meant a layer consisting of one or more layers of different materials, deposited on the upper surface of a block copolymer, and having alternately areas neutral and non-neutral (affines) with respect to the blocks of the underlying block copolymer.

By “increased thickness” is meant, within the meaning of the invention, an excess in thickness of the guide resin in the guide surface, the thickness preferably being measured by the distance between the two interfaces of the guide surface, the increased thickness having a greater distance than the distance between the two interfaces of the guide surface.

The applicant has developed a new method dedicated to the field of electronics by directed self-assembly, allowing different dimensions D to be created in the nanolithography mask independently of the natural period of the block copolymer without generating defects. In addition, the method developed by the applicant allows the shape and dimensions in the nanolithography mask to be varied at will in order to nanostructure a substrate with different dimensional nanostructures.

The invention relates to a method as shown in FIGS. 2, 3, and 4 comprising generating a guide surface 11 over a substrate 10, and then depositing an unassembled block copolymer layer 20 on the guide surface 11. In order to prevent any dewetting of the unassembled block copolymer, the method comprises forming a crosslinked polymer layer TC over the unassembled block copolymer layer. The stack thus created is thermally annealed at the assembly temperature Tass of the unassembled block copolymer in order to form a nanostructured block copolymer in the form of blocks, wherein the blocks are nanostructured in the form of nanodomains 21, 22 oriented in a perpendicular manner Z1 facing the neutral areas of the crosslinked polymer layer TC or on a parallel manner Z2 facing the non-neutral areas of the crosslinked polymer layer TC. The crosslinked polymer layer TC is subsequently removed, preferably by etching, together with one of the nanostructured blocks so as to form patterns of a nanolithography mask. The mask is then used to etch the substrate and obtain a nanostructured substrate having nanostructures of different dimensions.

To this end, the substrate surface can be neutralized or pseudo-neutralized. The substrate 10 is preferably solid and of any nature (oxide, metal, semiconductor, polymer . . . ) depending on the applications for which it is intended. Preferably, but not exhaustively, the material constituting the substrate can be selected from: silicon Si, a silicon oxide SixOy, silicon nitride Si3N4, a silicon oxynitride SixNyOz, an aluminum oxide AIxOy, a titanium nitroxide TixOyNz, a hafnium oxide HfxOy, metals, organic layers of the SoC (English acronym for “Spin on Carbon”) or BARO (English acronym for “bottom anti-reflectant coating”) type, or flexible substrates made of polydimethylsiloxane PDMS, for example.

In order to allow for the neutralization or pseudo-neutralization of its surface, the substrate 10 may or may not have patterns, said patterns being predrawn by a lithographic step or a sequence of lithographic steps of any nature prior to the step of depositing the first layer 20 of block copolymer BCP. Said patterns are intended to guide the organization of said block copolymer BCP by the so-called chemoepitaxy technique, FIGS. 2 and 3, or the so-called graphoepitaxy technique, FIG. 4, or a combination of these two techniques, to obtain a guide surface over the substrate.

The guide surface has areas neutral and non-neutral with respect to the unassembled block copolymer layer. In addition, at least one of said neutral or non-neutral areas of the guide surface has a first dimension.

According to one embodiment shown in FIG. 4, the guide surface involves implementing a graphoepitaxy technique using a guide resin. According to this embodiment, the guide resin has increased thicknesses. The increased thicknesses preferably have etching properties similar to one of the blocks of the block copolymer. In addition, etching of the guide resin can be carried out in either a positive or negative mode. In the negative mode T1a, only the exposed regions of the guide resin are transferred into the substrate. Conversely, in the positive mode T1b, only the unexposed regions of the guide resin are transferred into the substrate. In other words, in the negative mode, the guide resin behaves during etching as the at least one block removed (etched) of the assembled block copolymer. Thus, the guide resin is etched along with said block. In the positive mode, the guide resin behaves during etching as the non-removed (unetched) block(s) of the assembled block copolymer. Thus, this makes the guide resin resistant to etching.

In addition, the guide resin may be neutral with respect to the block copolymer, resulting after the block copolymer has been assembled, in a perpendicular orientation of its nanodomains to its lower interface.

However, the guide resin may also be non-neutral with respect to the block copolymer, resulting after the block copolymer has been assembled, in a parallel orientation of its nanodomains to its lower interface.

A particular example consists in grafting a layer of a statistical copolymer having a judiciously selected ratio of the same monomers as those of the block copolymer BCP 20 deposited thereon. The layer of the statistical copolymer allows the initial affinity of the substrate for the block copolymer BCP 20 to be balanced. The grafting reaction can be obtained by any thermal, photochemical, or oxidation-reduction means, for example.

This guide surface 11 advantageously allows the block copolymer, preferably the nanodomains of the block copolymer, to be guided, especially when assembling the block copolymer so as to obtain commensurate areas.

This also allows the defects induced when the period of the block copolymer is constrained to be reduced.

The guide surface 11 thus participates in the creation of patterns of different dimensions for a same block copolymer, especially the non-neutral areas, allowing variable dimensions.

When the guide surface 11 has been generated over the substrate 10, the method comprises depositing the unassembled block copolymer layer 20 on the guide surface as shown in FIGS. 2, 3, and 4.

As regards this unassembled block copolymer, the block copolymer BCP comprises “n” blocks, n being any integer greater than or equal to 2. The block copolymer BCP is more specifically defined by the following general formula:

A-b-B-b-C-b-D-b- . . . -b-Z

where A, B, C, D, . . . , Z are as many blocks “i” . . . “j” representing either pure chemical entities, that is to say each block is a set of monomers of identical chemical nature, polymerized together, or a set of co-monomers copolymerized together, in whole or in part, in the form of a block or statistical or random or gradient or alternating copolymer.

Each of the blocks “i” . . . “j” of the block copolymer BCP to be nanostructured can therefore potentially be written as: i=aᵢ-co-bᵢ-co- . . . -co-zᵢ, with i≠ . . . ≠j, in whole or in part.

The volume fraction of each entity aᵢ . . . zᵢ can range from 1 to 99%, by monomer units, in each of the blocks i . . . j of the block copolymer BCP.

The volume fraction of each of the blocks i . . . j may range from 5 to 95% of the block copolymer BCP.

The volume fraction is defined as the volume of an entity relative to that of a block, or the volume of a block relative to that of the block copolymer.

The volume fraction of each entity of a block of a copolymer, or of each block of a block copolymer, is measured as described below. Within a copolymer in which at least one of the entities, or one of the blocks if it is a block copolymer, includes several co-monomers, it is possible to measure, by proton NMR, the molar fraction of each monomer in the whole copolymer, and then to go back to the mass fraction using the molar mass of each monomer unit. To obtain the mass fractions of each entity of a block, or each block of a copolymer, it is then sufficient to add the mass fractions of the constituent co-monomers of the entity or block. The volume fraction of each entity or block can then be determined from the mass fraction of each entity or block and the density of the polymer forming the entity or block. However, it is not always possible to obtain the density of the polymers, the monomers of which are copolymerized. In this case, the volume fraction of an entity or block is determined from its mass fraction and the density of the compound that represents the mass majority of the entity or block.

The molecular weight of the block copolymer BCP can range from 1000 to 500,000 g·mol⁻¹. The block copolymer BCP can have any type of architecture: linear, star (three- or multi-arm), graft, dendritic, comb.

Each of the blocks i, j of a block copolymer has a surface energy denoted γᵢ . . . γⱼ, which is specific thereto and which is a function of its chemical constituents, that is to say the chemical nature of the monomers or co-monomers constituting it. Similarly, the materials constituting a substrate each have their own surface energy value.

Each of the blocks i, . . . j of the block copolymer also has an interaction parameter of Flory-Huggins type, denoted: χᵢₓ, when it interacts with a given material “x”, which can be a gas, a liquid, a solid surface, or another polymer phase for example, and an interfacial energy denoted “γᵢₓ”, with γᵢₓ=γᵢ−(γₓ cos θᵢₓ), where θᵢₓ is the non-zero contact angle between the materials i and x, with material x forming a drop on material i. The interaction parameter between two blocks i and j of the block copolymer is thus denoted χᵢⱼ.

There is a relationship between γᵢ and the Hildebrand's solubility parameter δᵢ of a given material i, as described in document Jia et al., Journal of Macromolecular Science, B, 2011, 50, 1042. In fact, the Flory Huggins interaction parameter between two given materials i and x is indirectly related to the surface energies γᵢ and γₓ specific to the materials, so one can either speak in terms of surface energies or in terms of interaction parameter to describe the physical phenomenon appearing at the interface of the materials.

When referring to the surface energies of a material and those of a given block copolymer BCP, it is implied that the surface energies are compared at a given temperature, and this temperature is the temperature (or at least part of the temperature range) at which the BCP can self-organize.

This block copolymer layer is deposited by a conventional technique such as spin coating or “spin coating”. In addition, this layer may have a thickness of at least 10 nm.

The block copolymer is necessarily deposited in a liquid/viscous state so that it can nanostructure at the assembly temperature, in a subsequent annealing step.

Preferentially, but without limiting the invention, the block copolymer used has at least one block where a heteroatom such as silicon, germanium, titanium, hafnium, zirconium, or aluminum is present in all or part of the (co)monomers constituting said block.

Preferentially, but without limiting the invention, the block copolymer used is said to be “high-χ” (has a high Flory-Huggins parameter), that is to say it must have a parameter greater than that of the so-called “PS-b-PMMA” system at the assembly temperature under consideration, as defined by Y. Zhao, E. Sivaniah and T. Hashimoto, Macromolecules, 2008, 41 (24), pages 9948-9951 (Determination of the Flory-Huggins parameter between styrene (“S”) and MMA (“M”):

χSM=0.0282+(4.46/T))

The method according to the invention comprises, after the unassembled block copolymer layer 20 has been deposited, forming a crosslinked polymer layer TC over the unassembled block copolymer layer 20. This layer is subjected to one or more localized crosslinking reaction(s) in order to define, within the crosslinked copolymer layer, adjacent areas which are alternately neutral and non-neutral with respect to the blocks of the underlying block copolymer. In addition, at least one of said non-neutral areas of the crosslinked polymer layer has a second dimension.

A subsequent step of annealing at the assembly temperature the underlying block copolymer 20 then allows the block copolymer to be nanostructured and nanostructured blocks comprising nanodomains 21, 22 oriented in a perpendicular manner Z1 at the interfaces facing the neutral affinity areas and nanostructured blocks comprising nanodomains 21, 22 oriented in a parallel manner Z2 at the interfaces facing the non-neutral areas, to be obtained.

The crosslinked polymer layer and one of the blocks of the block copolymer facing the neutral areas of the crosslinked polymer layer, that is to say the blocks of the block copolymer in which the nanodomains are oriented in a perpendicular manner Z1 at the interfaces, are then removed by etching. Where the removal of one of the blocks is a removal of only part of the nanodomains of one of the blocks of the nanostructured block copolymer, in particular of only the perpendicular nanodomains of said block, so that the parallel nanodomains of at least two blocks of the nanostructured block copolymer form patterns of the nanolithography mask. In other words, at least one of the nanodomains 22 of a block of the nanostructured block copolymer facing the neutral areas of the crosslinked polymer layer, oriented in a perpendicular manner to the interfaces, is removed by etching. Thus, according to the method, only the patterns M1, M2, M3 are retained, which are intended to form the patterns of the nanolithography mask. Furthermore, and quite advantageously, the patterns M1, M2 and M3 do not have the same dimension.

The various etching steps are preferably carried out by plasma etching. They can also be carried out successively, in a same etching frame, by plasma etching by adjusting the gas chemistry according to the constituents of each of the layers to be removed. For example, the chemistry of the constituent gases of the plasma will have to be adjusted according to the materials to be removed in order not to present a particular selectivity for one block of the block copolymer BCP.

Thus, by creating patterns in the crosslinked polymer layer which are not commensurate with the neutral or non-neutral areas of the guide surface 11, the method allows, after the unassembled block copolymer layer is nanostructured, areas of different dimensions to be created which can be used to nanostructure a substrate having nanostructures (patterns) of different dimensions.

According to the invention, a first embodiment as shown in FIG. 2 can be implemented to form a crosslinked polymer layer over the unassembled block copolymer layer.

To this end, following the step of depositing the block copolymer film BCP 20, a first prepolymer layer, denoted pre-TC 30 in FIG. 2, is deposited on the surface of the block copolymer BCP 20. This prepolymer layer is deposited on the block copolymer 20 by a conventional deposition technique, for example spin coating or “spin coating”, and is in a liquid/viscous state.

This prepolymer composition layer comprises one or more monomer(s) and/or dimer(s) and/or oligomer(s) and/or polymer(s) in solution.

Preferably, the prepolymer composition is formulated in a solvent that is orthogonal to the block copolymer layer 20 already present on the substrate, and comprises at least:
one monomer, dimer, oligomer, or polymer chemical entity, or any mixture of these various entities, of totally or partly identical chemical nature, and at least one crosslinkable functional group capable of ensuring the propagation of the crosslinking reaction under the effect of a stimulus; and
one or more chemical entities, also called crosslinking agents, capable of initiating the crosslinking reaction under the effect of the stimulus, such as a radical generator, an acid, and/or a base.

The solvent of the prepolymer layer is selected to be entirely “orthogonal” to the polymer system of the underlying layer in order to avoid any re-dissolution of this polymer in the solvent of the prepolymer layer during the deposition step (by spin-coating for example). The solvents in each respective layer will therefore be highly dependent on the chemical nature of the polymer material already deposited on the substrate. Thus, if the already deposited polymer is low polar/protic, since its solvent is selected from low polar and/or low protic solvents, the prepolymer layer can thus be solubilized and deposited on the first polymer layer from rather polar and/or protic solvents. Conversely, if the polymer already deposited is rather polar/protic, the solvents of the prepolymer layer may be selected from low-polar and/or low-protic solvents. The prepolymer composition may, in one embodiment variant, be used without a solvent.

The prepolymer layer is then subjected to a first stimulation localized on first areas, referenced TC1 in FIG. 2, said stimulation being selected from light radiation, ion bombardment, thermal stimulation, plasma, or an electrochemical process. This stimulation then causes a crosslinking reaction of the molecular chains of the prepolymer by the action of a first crosslinking agent in said first areas TC1 subjected to said stimulation. The first crosslinked areas obtained then exhibit a first affinity with respect to the blocks of the block copolymer.

Preferably, the stimulus is of an electrochemical nature and applied via an electron beam or light radiation, and even more preferably it is light radiation.

In a particularly advantageous embodiment, the crosslinking reaction of the components of the pre-TC prepolymer layer is activated by exposing the layer to light radiation, such as radiation in wavelength ranges from ultraviolet to infrared. Preferably, the illumination wavelength is between 10 nm and 1500 nm, and more preferably, it is between 100 nm and 500 nm. In one particular embodiment, the light source for exposing the layer to the light radiation may be a laser device. In such a case, the wavelength of the laser will preferably be centered on one of the following wavelengths: 436 nm, 405 nm, 365 nm, 248 nm, 193 nm, 172 nm, 157 nm, or 126 nm. Such a crosslinking reaction has the advantage of being performed at ambient or moderate temperature, preferably less than or equal to 150° C., and more preferably less than or equal to 110° C. It is also very fast, from about a few seconds to a few minutes, preferably less than 2 minutes. Preferably, the constituent compounds of the prepolymer layer, before crosslinking, are stable in solution as long as they are protected from exposure to the light source. They are thus stored in opaque containers. When such a prepolymer layer is deposited on the underlying layer, the constituents, which are stable in solution, are subjected to the light radiation allowing the crosslinking of the layer over a truly short period (typically less than 2 minutes). Thus, the prepolymer layer, in the areas TC1 subjected to radiation, does not have time to dewet. Furthermore, as the reaction propagates, in the exposed areas, the size of the chains increases, which limits the solubilization and inter-diffusion problems at the interface when the latter is in a “liquid/liquid” configuration.

The reaction of crosslinking by irradiation of the prepolymer layer may take place at a moderate temperature, much lower than the glass transition temperature of the underlying copolymer layer 20, so as to promote the diffusion of the reactive species and thus to increase the rigidity of the crosslinked network.

According to one variant of the invention, the light irradiation of the prepolymer layer is performed directly on a stack brought to the desired temperature, preferably below 110° C., to optimize the total reaction time.

This photo-crosslinking step can be carried out through a lithography mask. In one embodiment variant, it is also possible to use a local light source, of the laser type for example, to carry out the local irradiation of the prepolymer layer, without having to use a lithography mask.

Preferably a step of rinsing the locally crosslinked polymer layer TC1 is carried out so as to remove the non-crosslinked areas and form recessed areas in the locally crosslinked polymer layer TC1. To this end, the layer stack is rinsed, a step denoted “R” in FIG. 2, in a solvent orthogonal to the block copolymer BCP.

The locally crosslinked polymer layer can then be subjected to a post-exposure bake (denoted by its Anglo-Saxon acronym PEB “Post Exposure Bake”), at a temperature below the assembly temperature of the block copolymer. Such annealing then allows the diffusion of acids or bases released during exposure. Typically, the PEB of the locally crosslinked polymeric layer is carried out at a temperature of around 90° C. for a period of around 3 minutes. This layer may optionally comprise a thermal latent crosslinking agent, such as ammonium triflate.

Following rinsing and annealing of the locally crosslinked polymer layer, the method may comprise depositing a second prepolymer layer TC2. This layer is then deposited, on the one hand, on the previously crosslinked areas of the locally crosslinked polymer layer TC1 and, on the other hand, on the surface of the block copolymer not covered by the locally crosslinked polymer layer and corresponding to the recessed areas of the locally crosslinked polymer layer TC1.

This second prepolymer composition layer TC2, which may or may not be neutral with respect to the underlying block copolymer, (but of opposite affinity to the locally crosslinked polymer layer TC1) is then crosslinked, for example by light irradiation, by an electrochemical process, plasma, an ion bombardment, or a chemical species, in order to avoid the occurrence of a dewetting phenomenon of the block copolymer 20 when it nanostructures, during the subsequent annealing step at the assembly temperature Tass of the block copolymer. Crosslinking of the second prepolymer layer TC2 is initiated so as to obtain crosslinked areas having a second affinity with respect to the blocks of the block copolymer, the second affinity being opposite to the first affinity.

Thus, and as shown in the example in FIG. 2, the first locally crosslinked polymer layer TC1, for example, does not have a privileged affinity for one of the blocks of the underlying block copolymer 20 so that, when the block copolymer is assembled, the nanodomains located under the first crosslinked areas TC1 will orient in a perpendicular manner Z1 to the interfaces; while the second crosslinked layer TC2 has a non-neutral affinity with respect to one of the blocks of the underlying block copolymer so that, when the block copolymer is assembled, the nanodomains located under the second crosslinked areas TC2 will orient in a parallel manner Z2 to the interfaces.

These two crosslinked layers TC1 and TC2 allow a crosslinked polymer layer TC having adjacent crosslinked areas of opposite affinity with respect to the underlying block copolymer and of non-equivalent dimension, to be generated. Preferably, the crosslinked polymer layer TC has at least one non-neutral area of a dimension different from the neutral area. Alternatively, the crosslinked polymer layer may have at least two non-neutral areas of different dimensions.

In general, the different deposition steps of the successive layers can be carried out by any method known to microelectronics selected from: doctor-blade deposition, Langmuir-Blodgett deposition, chemical vapor deposition, physical vapor deposition, atomic thin film deposition, or spin-coating deposition. Preferably, but without limitation, depositions are made by the spin-coating technique.

After the crosslinked polymer layer is obtained, comprising crosslinked areas alternately neutral and non-neutral with respect to the underlying block copolymer BCP, the solubilization of the crosslinked polymer layer in the underlying block copolymer layer BCP 20 is strongly limited or even prevented and the occurrence of a dewetting phenomenon is delayed or even prevented.

According to one alternative embodiment, when two prepolymer layers form the crosslinked polymer layer, it is possible to structure only one or the other prepolymer layer. Thus, in the case of two prepolymer layers of opposite affinity, a first affinity first prepolymer layer can be crosslinked, and then annealed. The non-crosslinked areas of said prepolymer layer are then rinsed so as to form areas of the underlying block copolymer not covered by the first crosslinked prepolymer layer. A second prepolymer layer of an affinity opposite to the first layer is deposited so as to cover the not-covered areas of the block copolymer. Annealing is then carried out and the block copolymer is assembled.

In this way, for a same series of patterns, different lithographic masks can be used depending on the affinity of the initially exposed prepolymer layer.

The next step consists in subjecting the resulting stack to thermal annealing, at an assembly temperature of the block copolymer, so as to allow self-assembly of the block copolymer into nanodomains 21, 22.

The assembly temperature depends on the block copolymer used. In general, it is higher than 100° C., and even more preferably it is higher than 200° C., while being lower than a possible degradation temperature of said block copolymer. Preferably, the assembly temperature Tass of the block copolymer is lower than the glass transition temperature Tg of the polymer layer in its crosslinked and lithographed form or at least lower than a temperature at which the material(s) of the polymer layer behave(s) as a viscoelastic fluid. This temperature then lies in a temperature range, corresponding to this viscoelastic behavior, above the glass transition temperature Tg of the polymer layer material. Thermal annealing is carried out for a specific period, preferably less than 60 minutes and more preferably less than 5 minutes, in order to cause nanostructuring of the block copolymer. The nanodomains 21, 22 located under the crosslinked neutral areas TC1 with respect to the block copolymer are then oriented in a perpendicular manner Z1 to the interface with the crosslinked polymer layer, and the nanodomains 21, 22 located under the crosslinked non-neutral areas TC2 are oriented in a parallel manner Z2 to the interface with the crosslinked polymer layer.

Thus, it is possible, thanks to the method, to create neutral and non-neutral areas of mutually equivalent or non-equivalent dimensions. It is also possible to create several non-neutral areas, each of said non-neutral areas also being of mutually equivalent or non-equivalent dimensions and preferably of mutually non-equivalent dimensions. By non-equivalent is meant different dimensions, within the meaning of the invention. Thus, each neutral or non-neutral area may have its own dimension such as length, depth or height, or width. Preferably, the crosslinked polymer layer TC has at least one non-neutral area with dimensions different from those of the neutral area. Alternatively, the crosslinked polymer layer may have at least two non-neutral areas of different dimensions.

In the embodiment shown in FIG. 2, the areas of the block copolymer selected for forming the patterns M1, M2, M3 for nanostructuring the substrate are the areas located under the areas TC1 and under the areas TC2 of the crosslinked polymer layer.

In the example shown in FIG. 2, the first layer of the crosslinked polymer does not have a preferential affinity with respect to one of the blocks of the underlying block copolymer, so that in the areas of the copolymer BCP covered by this layer, the nanodomains 21, 22 spontaneously orient in a perpendicular manner Z1 to the interfaces. The second layer of the crosslinked polymer layer, of an affinity opposite to the first layer, has a neutral affinity with respect to one of the blocks of the underlying block copolymer, so that in the areas of the copolymer BCP covered by this layer, the nanodomains 21, 22 spontaneously orient in a parallel manner Z2 to the interfaces. In this case, in the annealing step at the self-assembly temperature Tass, the nanodomains 21, 22 located under the first layer of the crosslinked polymer layer of the block copolymer orient in a perpendicular manner Z1 to the interfaces, while the nanodomains 21, 22 located under the second layer of the crosslinked polymer layer orient in a parallel manner Z2 to the interfaces.

Prior to the step of etching G1 the stack, a preliminary etching step Ga is carried out, preferably by plasma, to remove the crosslinked polymer layer, so as to uncover the nanodomains 21, 22 of the nanostructured block copolymer oriented in a perpendicular manner Z1 or in a parallel manner Z2. One way of removing the crosslinked polymer layer consists in using dry etching, such as plasma, for example with suitable gas chemistry, such as an oxygen-predominant base in a mixture with a gas that is rather inert such as He, Ar, for example. Such dry etching is all the more advantageous and easier to achieve if the underlying block copolymer BCP 20 contains, for example, silicon in one of its blocks, which then acts as an etch stop layer.

The step of etching G1 the stack is then carried out; at least one of the nanodomains 22 oriented perpendicular to the interfaces can be removed, so as to form a pattern M1. In this case, the nanodomains 21 left for forming the pattern M1 must be able to withstand the etching. To this end, the blocks corresponding to the nanodomains 21 and intended to be retained, may for example contain silicon, which then acts as an etch stop layer.

Alternatively, at least one of the nanodomains 21 oriented perpendicular to the interfaces may be removed so as to form a pattern M1. In this case, the nanodomains 22 left for forming the pattern M1 must be able to withstand the etching. To this end, the blocks corresponding to the nanodomains 22 and intended to be retained, may for example contain silicon, which then acts as an etch stop layer.

In addition, the areas Z2 are retained and are also intended to form patterns M2, M3 transferred into the underlying substrate by etching. The transfer properties of these areas may be different, with the area Z1 comprising only one type of perpendicular nanodomain and while the area Z2 comprises nanodomains 21 and 22 oriented in a parallel manner. However, this disadvantage is quite minor and can be easily circumvented by increasing the thickness of the BCP film to compensate for any difference in depth transferred from a pattern in the area Z1. In addition, etching of the guide surface and more particularly the guide resin can be performed in either a positive or negative mode.

A discontinuous block copolymer film is then obtained in which a plurality of patterns M1, M2, M3 are created and separated from each other, while having different dimensions. In addition, the areas of the block copolymer located under the neutral areas of the crosslinked polymer layer have nanodomains oriented perpendicular to the interfaces and the dimension of the nanodomains corresponds to the first dimension of the areas.

Alternatively, the areas of the block copolymer located under the non-neutral areas of the crosslinked polymer layer have nanodomains oriented parallel to the interfaces, and the dimension of the nanodomains corresponds to the first dimension of the areas.

Once the patters M1, M2, M3 are obtained, a discontinuous and porous film is obtained, forming a nanolithography mask, and having a plurality of patterns M1, M2, M3, etc., separated from each other, and intended to be transferred into the underlying substrate 10.

Preferably, this transfer step can be carried out by plasma etching, in the same dry etching frame, simultaneously with or successively to the etching step G1 of removing the at least one nanodomain 22 or 21. For example, the frame can be an ICP (Inductively Coupled Plasma) reactor or a CCP (Capacitively Coupled Plasma) reactor.

Thus, successive stacks of materials with a particular atomic constitution allow the pattern to be transferred very selectively in the different layers by plasma etching with very distinct gas chemistries, allowing a substrate to be deeply etched. The substrate, for example silicon, can be plasma-etched with halogen chemistry (SF₆, CH₃F, CH₂F₂, CHF₃, CF₄, HBr, Cl₂). The patterns are then transferred into the substrate which is etched T1a and T1b.

By way of example, in the case where the block copolymer contains a heteroatom such as silicon in one of its blocks, and the polymer layer is entirely organic or halo-organic, plasma gas chemistry for the etching steps can be an oxygen-fluorinated mixture as selected from O₂/CF₄, O₂/CHF₃, O₂/CH₂F₂, O₂/CH₃F, O₂/SF₆, HBr/O₂, or HBr/Cl₂/O₂ to which a diluent gas such as He or Ar can be added.

The patterns M1, M2, M3 thus created have equivalent or non-equivalent dimensions, preferably the patterns M2, M3 have non-equivalent dimensions. The patterns M1, M2, M3 are intended to be transferred by etching(s) into the thickness of the underlying substrate, each pattern corresponding to a nanostructure intended to nanostructure the substrate.

Thus, the non-neutral areas can be used as a new lithography resin and provide new dimensions for nanostructuring the underlying substrate.

The method according to the invention allows patterns to be created, depending on the crosslinked polymer layer used (neutral or non-neutral) as well as thanks to its different crosslinking reactions, in the unassembled block copolymer layer which are not commensurate with the patterns of the guide layer. Thus, after the BCP is assembled, blocks of different dimensions according to the areas Z1 or Z2 can be used to nanostructure the substrate having nanostructures of different dimensions.

A second embodiment is shown in FIGS. 3 and 4.

In this embodiment, the crosslinked polymer layer is formed from a prepolymer composition comprising, on the one hand, a plurality of functional monomers and at least one crosslinkable functional group within its polymer chain and, on the other hand, two chemically different crosslinking agents, each agent being capable of initiating the crosslinking of said prepolymer in response to a stimulation specific thereto.

Advantageously, this allows the crosslinked polymer layer to be structured. In addition, such a layer allows the number of steps of the method to be reduced and also the method to be simplified. In fact, a single prepolymer composition layer is deposited, and the subsequent crosslinking step is optimized by the presence of each agent capable of initiating crosslinking. Thus, it is no longer necessary to deposit a first layer and then crosslink said first layer and then re-redeposit a second layer which must also be subjected to crosslinking. This also saves time.

According to this embodiment, two successive crosslinking reactions are carried out in primary TC1 and secondary TC2 areas of said prepolymer layer, by successively stimulating the two crosslinking agents, in order to cause a crosslinking reaction of the molecular chains of said prepolymer by the successive action of the first crosslinking agent in said primary areas TC1 subjected to said first stimulation and then of the second crosslinking agent in said secondary areas TC2 subjected to said second stimulation, in order to obtain a crosslinked polymer layer, wherein the different adjacent crosslinked areas have an opposite affinity to one another with respect to the nanodomains 21, 22 of the blocks of the underlying block copolymer.

The first and second successive stimulations, allowing primary areas TC1 and secondary areas TC2 to be crosslinked within the polymer layer, can be selected from: light radiation, ion bombardment, thermal stimulation, plasma, or an electrochemical process.

The two stimulations can be of different or identical nature. However, if they are of the same nature, the selective activation of each crosslinking agent is done by selecting a different stimulation setting. Thus, for example, if the two successive stimulations are carried out by ultraviolet (UV) radiation, then the activation wavelength of each crosslinking agent is different. Similarly, if the two successive stimulations are carried out thermally, then the activation temperature of each crosslinking agent is different.

When the stimulation is carried out by light radiation, it is generally through a photolithography mask. However, the use of a laser device, for example, allows certain areas to be irradiated locally and precisely without the need for a mask. Similarly, it is possible to stimulate certain areas thermally and locally by means of an infrared laser device or via a mechanical means such as the heating tip of an atomic force microscope. Depending on the means used to carry out the successive stimulations, each stimulation can therefore be carried out through a mask or not.

In addition, the first crosslinking agent can initiate crosslinking by reacting with a first crosslinkable functional group of the polymer chain, while the second crosslinking agent can initiate crosslinking by reacting with a crosslinkable functional group identical to or different from the first one.

In addition, one of the two crosslinking agents can also react with at least one functional group of the polymer chain of the prepolymer.

In addition, either or both of the crosslinking agents may be carried by the polymer chain of said prepolymer.

Preferably, each crosslinking agent is present, in the prepolymer composition, with a content less than or equal to 30% of the total mass of said prepolymer composition.

Advantageously, after the step of double crosslinking, the crosslinked polymer layer obtained comprises neutral crosslinked areas TC1 and non-neutral crosslinked areas TC2, which may or may not be of mutually equivalent dimensions. Preferably, the non-neutral reticulated areas have mutually different dimensions.

In addition, a same crosslinked neutral area is intended to allow the formation, in an underlying area of the block copolymer, of nanodomains oriented in a perpendicular manner Z1. After removal of one or more perpendicularly oriented nanodomains and one of the blocks of the assembled block copolymer, the resulting pattern M1, M2, M3 is capable of transferring into an underlying substrate by etching. In addition, the non-neutral areas TC2 are also intended to allow the formation, in an underlying area of the block copolymer, of nanodomains oriented in a parallel manner Z2. The pattern M2, M3 obtained by these parallel-oriented nanodomain blocks after removal of the crosslinked polymer layer is also capable of being transferred into the underlying substrate by etching.

Thus, thanks to the invention, parallel-oriented nanodomains participate in the creation of patterns in the substrate. In addition, the patterns created have different periods with a minimum of defects. Thus, thanks to the guide surface and the crosslinked polymer layer, it becomes possible to create different dimensions in the BCP, regardless of its natural period. One of the major interests of the invention is therefore to use the non-neutral areas created in the BCP (parallel-oriented nanodomains) as a lithography resin in its own right, and then to transfer these patterns into the substrate at the same time. These non-neutral areas are therefore an integral part of the final pattern. In addition, it is therefore possible to vary at will the patterns created in the BCP, while multiplying the different dimensions for a same pattern.

The choice of removing one or more perpendicular-oriented Z2 nanodomains 21, 22 to obtain one or more patterns depends on the type of structure that is to be obtained at the end of the method.

Whether the first or the second embodiment is used, the crosslinked polymer layer preferably has areas neutral and non-neutral with respect to the underlying unassembled block copolymer layer. The crosslinked polymer layer preferably has at least one non-neutral area of a dimension different from the dimensions of the neutral areas.

In addition, at least one of the non-neutral areas of the crosslinked polymer layer has a second dimension. Preferably, the first and second dimensions are different so as to generate in the nanolithography mask patterns of different dimensions and nanostructures in the substrate of different dimensions after etching.

1. A method for nanostructuring a substrate for the preparation of a nanostructured substrate having nanostructures of different dimensions, said method comprising the following steps:
Generating a guide surface over a substrate;
Depositing an unassembled block copolymer layer on the guide surface, said unassembled block copolymer layer being capable of forming, after assembly, a nanostructured block copolymer in the form of nanodomains;
Forming a crosslinked polymer layer over the unassembled block copolymer layer;
Annealing at a temperature corresponding to an assembly temperature of the unassembled block copolymer layer;
Removing the crosslinked polymer layer and at least part of one of block of the nanostructured block copolymer so as to form patterns of a nanolithography mask;
Etching the substrate by means of said nanolithography mask;
wherein:
said guide surface has areas neutral and non-neutral with respect to the unassembled block copolymer layer, at least one of said neutral or non-neutral areas of the guide surface having a first dimension;
said crosslinked polymer layer has areas neutral and non-neutral with respect to the unassembled block copolymer layer, at least one of said non-neutral areas of the crosslinked polymer layer having a second dimension;
said removal of said at least part of one of the blocks being a removal of only perpendicular nanodomains of said block, so that parallel nanodomains of at least two blocks of the nanostructured block copolymer form patterns of the nanolithography mask; and
said first and second dimensions are different so as to generate in the nanolithography mask patterns of different dimensions and nanostructures in the nanostructured substrate of different dimensions after etching.

2. The method according to claim 1, wherein the non-crosslinked block copolymer layer has a thickness at least equal to 10 nm.

3. The method according to claim 1, wherein the crosslinked polymer layer has at least one non-neutral area of a dimension different from the neutral area.

4. The method according to claim 1, wherein generating the guide surface over the substrate involves implementing chemoepitaxy or graphoepitaxy.

5. The method according to claim 4, wherein the guide surface has guide resin increased thicknesses and the increased thicknesses have etching properties similar to one of the blocks of the block copolymer.

6. The method according to claim 5, wherein the guide resin forming the increased thicknesses is non-neutral with respect to the block copolymer.

7. The method according to claim 5, wherein the guide resin forming the increased thicknesses is neutral with respect to the block copolymer.

8. The method according to claim 5, wherein etching of the guide resin is carried out in a positive mode.

9. The method according to claim 5, wherein etching of the guide resin is carried out in a negative mode.

10. The method according to claim 1, wherein areas of the block copolymer located under the neutral areas of the crosslinked polymer layer have nanodomains oriented perpendicular to interfaces between the block copolymer and the crosslinked polymer, and a dimension of the nanodomains corresponds to the first dimension of the non-neutral areas of the guide surface.

11. The method according to claim 1, wherein areas of the block copolymer located under the non-neutral areas of the crosslinked polymer layer have nanodomains oriented parallel to interfaces between the block copolymer and the crosslinked polymer, and a dimension of the nanodomains corresponds to the first dimension of the non-neutral areas of the guide surface.

12. The method according to one of claim 1, wherein the block copolymer comprises at least one block where a heteroatom is present in all or part of the (co)monomers constituting said block.

13. The method according to claim 1, wherein the crosslinked polymer layer comprises at least two non-neutral reticulated areas which have mutually different dimensions.

14. The method according to claim 1, wherein the formation of the crosslinked polymer layer over the unassembled block copolymer layer includes the following sub-steps:
Depositing a first layer of a prepolymer composition (pre-TC) on the unassembled block copolymer layer;
Reacting by locally crosslinking molecular chains within said first prepolymer composition layer so as to generate a locally crosslinked polymer layer;
Rinsing the locally crosslinked polymer layer in order to remove the non-crosslinked areas;
Depositing a second prepolymer composition layer at least on the unassembled block copolymer layer;
Reacting by locally crosslinking molecular chains within said second prepolymer composition layer so as to generate a locally crosslinked polymer layer.

15. The method according to claim 1, wherein the formation of said crosslinked polymer layer over the unassembled block copolymer layer includes the following sub-steps:
depositing a prepolymer composition layer comprising, on the one hand, a plurality of functional monomers and at least one crosslinkable functional group within its polymer chain and, on the other hand, two chemically different crosslinking agents, each crosslinking agent being capable of initiating crosslinking of said prepolymer in response to a stimulation specific thereto, and
carrying out two successive crosslinking operations in primary and secondary areas of said layer, by successively stimulating the two crosslinking agents, in order to cause a crosslinking reaction of molecular chains of said prepolymer by the successive action of the first crosslinking agent in said primary areas subjected to said first stimulation and then of the second crosslinking agent in said secondary areas subjected to said second stimulation in order to obtain the crosslinked polymer layer in which the different primary and secondary crosslinked areas have an opposite affinity with respect to the blocks of the underlying block copolymer.

16. The method according to claim 12, said heteroatom being selected from among silicon, germanium, titanium, hafnium, zirconium, aluminum.
